(19) United States
(12) Patent Application Publication
(10) Pub. No.: US 2019/0107784 A1
(43) Pub. Date: Apr. 11, 2019

(54) PROJECTION LENS WITH A MEASUREMENT BEAM PATH

(71) Applicant: Carl Zeiss SMT GmbH, Oberkochen (DE)

(72) Inventors: Alexander WOLF, Essingen (DE); Toralf GRUNER, Aalen (DE)

(21) Appl. No.: 16/152,831

(22) Filed: Oct. 5, 2018

(30) Foreign Application Priority Data
Oct. 5, 2017 (DE) 10 2017 217 680.6

(51) Int. Cl. G03F 7/20

(52) U.S. Cl. CPC G03F 7/70591

(57) ABSTRACT

A projection lens (50) for a microlithographic projection exposure apparatus (10) includes a plurality of optical elements (M1-M8) for imaging mask structures (28) onto a surface (34) of a substrate (36) by way of projecting the mask structures using imaging radiation (14) that travels along a used beam path. At least one of the optical elements (M8) is formed with an opening (56) and the projection lens has a measurement beam path (66) extending through the opening.

### CROSS REFERENCE TO RELATED APPLICATIONS

This application claims priority to the German Patent Application No. 10 2017 217 680.6 filed on Oct. 5, 2017. The entire disclosure of this patent application is incorporated into the present application by reference.

### FIELD OF THE INVENTION

The invention relates to a projection lens for a microlithographic projection exposure apparatus, having a plurality of optical elements for imaging mask structures onto a surface of a substrate, to a projection exposure apparatus of that type, and to a method for measuring a projection lens.

### BACKGROUND

In order to image microstructures or nanostructures with great accuracy using a microlithographic projection exposure apparatus, it is important to know the current state of the projection lens. Required in particular is the most current information pertaining to alignment settings and possible surface deformations of the optical elements of the projection lens and contamination deposits on the optical elements etc. This information should be acquired if possible without interrupting the current imaging operation of the projection exposure apparatus.

### SUMMARY

It is an object of the invention to provide a projection lens, a projection exposure apparatus and a method of the type set forth above, by way of which the aforementioned problems are solved and state information of the projection lens that is relevant for the imaging operation of the projection exposure apparatus can be ascertained.

This object is addressed, according to one formulation of the invention, by a projection lens for a microlithographic projection exposure apparatus, having a plurality of optical elements for imaging mask structures onto a surface of a substrate by way of projecting the mask structures using imaging radiation that travels along a used beam path, wherein at least one of the optical elements is formed with an opening and the projection lens has a measurement beam path extending through the opening.

Due to the fact that a measurement beam path is provided which extends through an opening in at least one of the optical elements, it becomes possible to ascertain state information of the projection lens that is relevant for the imaging operation of the projection exposure apparatus. This can be accomplished in particular during the imaging operation of the projection exposure apparatus, and consequently in real time. The real-time ascertainment of the relevant state information makes possible a near-instantaneous correction, in particular a correction in real time, of any state deviations that occur.

In accordance with an embodiment, the opening is arranged in decentered, or decentralized, fashion in the optical element. In accordance with a further embodiment, the measurement beam path is tilted by at least 1° with respect to the used beam path at the site of the opening, in particular of the decentered opening. In particular, it is tilted by more than 2° or more than 5°. In other words, the orientation of the used beam path is tilted by the specified minimum angle with respect to the orientation of the measurement beam path at the site of the opening. The orientation of the corresponding beam path can be determined by the intensity-weighted average propagation direction of the radiation that is guided therein.

According to a further embodiment, the measurement beam path is incident on at least a further one of the optical elements, i.e. is reflected at a mirror if one is present, and passes through a lens element if one is present, and the projection lens is furthermore assigned a measurement apparatus, which is configured for measuring a property of the projection lens. According to an embodiment variant, the property to be measured comprises a surface shape of at least a section of the further optical element. Surface deformations, occurring e.g. due to temperature differences, of one or more optical elements on which the measurement beam path is incident can thus be measured.

According to a further embodiment, the property of the further optical element to be measured comprises a condition of at least one section of one or more surface layers of the further optical element. It is thus possible to measure e.g. layer changes, for example having thermal origin. These can manifest as a changed transmittance.

According to a further embodiment, the property of the further optical element to be measured comprises a transmission or reflection behavior of at least one section of the further optical element. A reduction of the transmission or reflection behavior caused by contamination or a change in the transmission or reflection behavior caused by thermal effects can thus be measured.

According to a further embodiment, the property to be measured comprises a lateral imaging stability of the projection lens, which is frequently also referred to as “line of sight”.

In accordance with a further embodiment, the optical element having the opening is configured as a mirror. Alternatively, it can be configured as a lens element. In accordance with an embodiment, the projection exposure apparatus is configured for operation in the EUV wavelength range.

According to a further embodiment, the optical element having the opening is the last optical element of the used beam path before an image plane. According to a further embodiment, at least one of the optical elements is configured as a mirror which is operated with grazing incidence in the used beam path. Such a mirror can also be referred to as “G mirror”.

According to a further embodiment, the projection lens is assigned a measurement apparatus for the ellipsometric measurement of measurement radiation that is guided in the measurement beam path. For example, polarized measurement radiation is thus radiated into the measurement beam path, and the polarization state thereof after passage through the measurement beam path is measured.

Furthermore provided according to the invention is a microlithographic projection exposure apparatus having the projection lens in one of the above-described embodiments or embodiment variants.

According to an embodiment of the projection exposure apparatus, the measurement beam path extends such that it is usable during an imaging operation of the projection exposure apparatus.

Furthermore provided according to the invention is a method for measuring a projection lens for a microlithographic projection exposure apparatus. The projection exposure apparatus comprises a plurality of optical elements for imaging mask structures onto a surface of a substrate by way of projecting the mask structures using imaging radiation that travels along a used beam path, wherein at least one of the optical elements is formed with an opening. The method comprises radiating measurement radiation through the opening of the at least one optical element.

Furthermore, the features indicated with regard to the abovementioned embodiments or embodiment variants of the projection lens according to the invention or the projection exposure apparatus according to the invention can be correspondingly applied to the method according to the invention, and vice versa. The embodiments of the method according to the invention that can be gathered therefrom are intended to be expressly comprised by the disclosure of the invention. Furthermore, the advantages mentioned above with respect to the embodiments of the projection lens according to the invention or the projection exposure apparatus according to the invention consequently also apply to the corresponding embodiments of the method according to the invention, and vice versa.

### BRIEF DESCRIPTION OF THE DRAWINGS

Exemplary embodiments of a microlithographic projection exposure apparatus according to the invention will be explained in more detail below with reference to the appended schematic drawings. In the figures:

FIG. 1 shows a schematic view of a microlithographic projection exposure apparatus having a projection lens, and

FIG. 2 shows a sectional view of an embodiment of the projection lens according to FIG. 1 having a measurement apparatus that is integrated therein.

### DETAILED DESCRIPTION

In the exemplary embodiments described below, elements which are functionally or structurally similar to one another are provided with the same or similar reference signs as far as possible. Therefore, for understanding the features of the individual elements of a specific exemplary embodiment, reference should be made to the description of other exemplary embodiments or the general description of the invention.

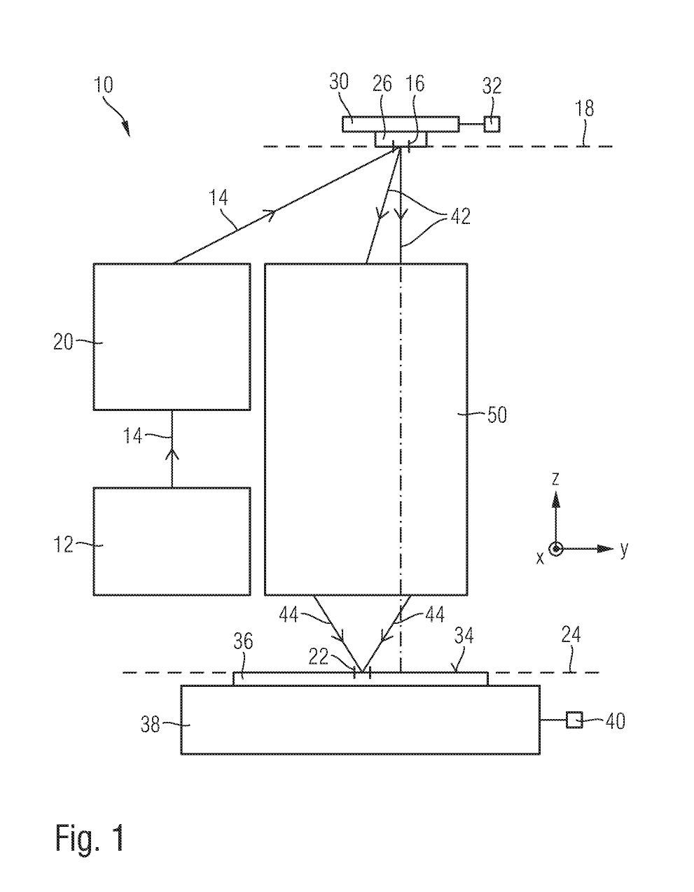

FIG. 1 illustrates a microlithographic projection exposure apparatus 10, comprising a radiation source 12 for used radiation or imaging radiation 14. The radiation source 12 in the present case is an EUV radiation source, which produces radiation in a wavelength range of e.g. between 5 nm and 30 nm, in particular between 5 nm and 15 nm. In particular, the radiation source 12 may be a radiation source with a wavelength of approximately 13.5 nm or a radiation source with a wavelength of approximately 6.9 nm. Other EUV wavelengths are also possible. In general, even arbitrary wavelengths are possible for the imaging radiation 14 guided in the projection exposure apparatus 10, for example visible wavelengths or other wavelengths which may find use in microlithography (e.g. DUV, deep ultraviolet) and for which suitable laser light sources and/or LED light sources are available (e.g. 365 nm, 248 nm, 193 nm, 157 nm, 129 nm, 109 nm). A beam path of the imaging radiation 14 is depicted very schematically in FIG. 1.

An illumination optical unit 20 serves to guide the imaging radiation 14 from the radiation source 12 to an object field 16 in an object plane 18. Using a projection lens 50, the object field 16 is imaged into an image field 22 in an image plane 24 with a specified reduction scale. In order to facilitate the description of the projection exposure apparatus 10 and the projection lens 50, a Cartesian xyz-coordinate system is indicated in the drawing, from which system the respective positional relationship of the components illustrated in the figures is evident. In FIG. 1, the x-direction runs perpendicular to the plane of the drawing out of the latter. The y-direction runs towards the left, and the z-direction runs upward.

The object field 16 and the image field 22 are rectangular. Alternatively, it is also possible for the object field 16 and the image field 22 to have a bent or curved embodiment, that is to say, in particular, a partial ring shape. The object field 16 and the image field 22 have an x/y-aspect ratio of greater than 1. Therefore, the object field 16 has a longer object field dimension in the x-direction and a shorter object field dimension in the y-direction. These object field dimensions extend along the field coordinates x and y.

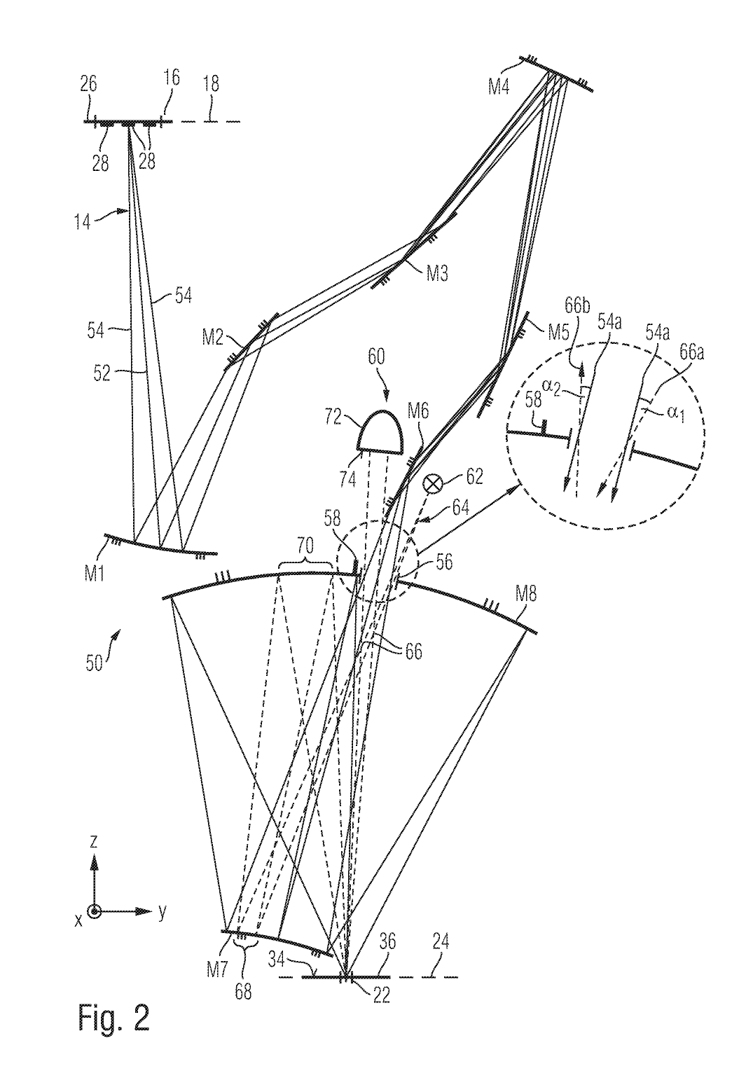

The exemplary embodiment depicted in FIG. 2 can be used for the projection lens 50. The projection lens according to FIG. 2 reduces by a factor 8. Other reduction scales are also possible, for example 4×, 5× or even reduction scales which are greater than 8×. The image plane 24 is arranged parallel to the object plane 18. Imaged here are mask structures 28, which are arranged on a section of a mask 26 which is operated in reflection (also referred to as reticle), said section coinciding with the object field 16. The mask 26 is carried by a reticle holder 30. The reticle holder 30 is displaced by a reticle displacement drive 32.

The imaging by way of the projection lens 50 is implemented onto the surface 34 of a substrate 36 in the form of a wafer, which is carried by a substrate holder 38. The substrate holder 38 is displaced by a wafer or substrate displacement drive 40.

FIG. 1 schematically illustrates, between the mask 26 and the projection lens 50, a ray beam 42 of the imaging radiation 14 that enters said projection lens and, between the projection lens 50 and the substrate 36, a ray beam 44 of the imaging radiation 14 that emerges from the projection lens 50. An image field-side numerical aperture (NA) of the projection lens 50 is not reproduced to scale in FIG. 1.

The projection exposure apparatus 10 is of the scanner type. Both the mask 26 and the substrate 36 are moved in the y-direction during the operation of the projection exposure apparatus 10 by way of corresponding actuation of the displacement drives 32 and 40. A stepper type of the projection exposure apparatus 10, in which a stepwise displacement of the substrate 36 in the x- and y-directions is effected between individual exposures of the substrate 36, is also possible.

As already mentioned above, FIG. 2 shows the optical design of an exemplary implementation of the projection lens 50. Furthermore, a used beam path of the imaging radiation 14 through the projection lens 50 is illustrated on the basis of three individual rays starting from an object field point. The individual rays comprise a chief ray 52, that is to say an individual ray travelling through the center of a pupil in a pupil plane of the projection lens 50, and a left and right coma ray 54 of the object field point.

The projection lens 50 according to FIG. 2 has a total of eight optical elements in the form of mirrors, which, proceeding from the object field 16, are numbered M1 to M8 in the order of the beam path of the individual rays 52 and 54. A projection lens 50 can also have a different number of mirrors, for example four mirrors or six mirrors. FIG. 2 illustrates the calculated reflection surfaces of the mirrors M1 to M8. What can be identified in the illustration according to FIG. 2 is that only a portion of these calculated reflection surfaces is used. Only this actually used region of the reflection surfaces is actually present in the real mirrors M1 to M8. These used reflection surfaces are carried in a known manner by mirror bodies.

In the projection lens 50 according to FIG. 2, the mirrors M1, M4, M7 and M8 are configured as mirrors for normal incidence, that is to say as mirrors on which the imaging radiation 14 is incident with an angle of incidence that is smaller than 45°. The mirrors M2, M3, M5 and M6 are mirrors for grazing incidence of the imaging radiation 14 (known as G mirrors), that is to say mirrors on which the imaging radiation 14 is incident with angles of incidence that are greater than 60°. A typical angle of incidence of the individual rays 52 and 54 of the imaging radiation 14 on the mirrors M2, M3 and M5, M6 for grazing incidence lies in the region of 80°. The mirrors M2 and M3 form a mirror pair arranged in series directly in the beam path of the imaging radiation 14. The mirrors M5 and M6 also form a mirror pair arranged directly in series in the beam path of the imaging radiation 14.

The mirrors M1, M4, M5 and M8 have negative values for the radius, i.e. are, in principle, concave mirrors. The mirrors M2, M3, M6 and M7 have positive values for the radius, i.e. are, in principle, convex mirrors. The mirrors M2, M3 and M6 for grazing incidence each have very large absolute values for the radius, that is to say they have a relatively small deviation from a planar surface. These mirrors M2, M3 and M6 for grazing incidence thus have practically no refractive power, that is to say practically no overall beam-forming effect like a concave or convex mirror, but rather contribute to specific and, in particular, local aberration correction.

The mirrors M1 to M8 carry a coating that optimizes the reflectivity of the mirrors M1 to M8 for the imaging radiation 14. This can be a ruthenium coating, a molybdenum coating or a molybdenum coating with an uppermost layer of ruthenium. In the mirrors M2, M3, M5 and M6 for grazing incidence, use can be made of a coating with e.g. one ply of molybdenum or ruthenium. These highly reflecting layers, in particular of the mirrors M1, M4, M7 and M8 for normal incidence, can be configured as multi-ply layers, wherein successive layers can be manufactured from different materials. Alternating material layers can also be used. A typical multi-ply layer can have fifty bilayers, respectively made of a layer of molybdenum and a layer of silicon.

The mirror M8, that is to say the ultimate mirror upstream of the image field 22 in the used beam path, has a passage opening 56 for the passage of the imaging radiation 14 which is reflected from the antepenultimate mirror M6 towards the penultimate mirror M7. The mirror M8 is used in a reflective manner around the passage opening 56. The passage opening 56 is arranged in decentered fashion in the mirror M8, specifically the passage opening 56 is displaced in the y-direction with respect to the mirror center 58 by at least 5% of the arc length of the region of the mirror M8 that is used in the y-z section plane. In the x-direction, the passage opening 56 in the present embodiment is arranged centrally in the mirror M8. In other embodiments, the passage opening can also be arranged in decentered fashion in the x-direction. The mirror M8 defines an image-side obscuration in the x-dimension which is less than 20% of the image-side numerical aperture of the projection optical unit 23. In the y-direction, the obscuration is significantly smaller and moreover decentered. With the obscuration it is possible to realize the projection lens 50 with a relatively high numerical aperture in an economically meaningful way.

None of the other mirrors M1 to M7 has passage openings and said mirrors are used in a reflective manner in a continuous region without gaps. Other embodiments in which further mirrors likewise have a passage opening are also possible. The mirrors M1 to M8 are embodied as free-form surfaces which cannot be described by a rotationally symmetric function. Other embodiments of the projection lens 50, in which at least one of the mirrors M1 to M8 is embodied as a rotationally symmetric asphere, are also possible. It is also possible for all mirrors M1 to M8 to be embodied as such aspheres. Further details relating to the fundamental design of the projection lens 50 (illustrated in FIG. 2) can be gathered in particular from the description relating to the embodiment of FIG. 6 in WO 2015/014753A1, the disclosure of which is incorporated into the present application by reference.

Furthermore assigned to the projection lens 50 in accordance with FIG. 2 is a measurement apparatus 60, comprising a measurement radiation source 62 and a detection system 72. In the present illustrated embodiment, the measurement apparatus 60 is integrated fixedly in the projection lens 50 and serves for monitoring one or more properties of the projection lens 50 during the imaging operation of the projection exposure apparatus 10, such that the wafer throughput of the projection exposure apparatus 10 is not reduced, or not notably reduced, by the measurement operation. Alternatively, the measurement apparatus 60 can also be arranged at the projection lens 50 merely for measurement purposes.

The measurement radiation source 62 serves for generating measurement radiation 64. The measurement radiation 64 can have a different wavelength than the imaging radiation 14, e.g. a wavelength in the visible wavelength range, in particular e.g. 632.8 nm, in the UV wavelength range, in particular the DUV wavelength range, e.g. 248 nm, the VUV wavelength range, e.g. 193 nm, or in the infrared range. The measurement radiation 64 can in particular comprise white light.

The beam path 66 of the measurement radiation 64 is illustrated in FIG. 2 on the basis of two marginal rays illustrated in dashed lines. Proceeding from the measurement radiation source 62, the measurement radiation 64 is radiated through the passage opening 56 of the mirror M8 onto an irradiation section 68 of the mirror M7. The measurement radiation source 62 is here arranged above the mirror M7 such that the measurement beam path 66 is tilted by the angle α₁ with respect to the used beam path of the imaging radiation 14 at the site of the passage opening 56. This situation is illustrated in FIG. 2 in the circular region in enlarged illustration. The orientation of the measurement beam path 66, defined by the average propagation direction of the measurement radiation 64, is illustrated here by way of the dashed arrow 66a. The orientation of the used beam path, defined by the average propagation direction of the imaging radiation 14, is illustrated by way of the arrow 54a. The angle α₁ between the straight lines defined by the arrows 54a and 66a is at least 1°, in particular at least 2° or at least 5°.

The measurement radiation 64 is reflected at the irradiation section 68 of the mirror M7 onto an irradiation section 70 of the mirror M8, from where the measurement radiation 64 is reflected onto the substrate 36. The measurement radiation 36 is also reflected at the surface 34 of the substrate 36 and once again passes through the passage opening 56 of the mirror M8, but this time in approximately the opposite direction. The reflection can take place at the substrate 36 within the image field 22, as in the embodiment illustrated in FIG. 2, or at a section of the substrate 36 that is located outside the image field 22.

If, in a suitable embodiment (not illustrated in the drawing) of the projection lens 50, the measurement radiation 64 is reflected at a section of the substrate 36 that is located outside the image field 22, the measurement radiation 64 may be guided via regions of the mirrors M7 and M8 that are not used by the beam path of the imaging radiation 14. In the case of appropriate shaping in these regions, the measurement beam path 66 can then, after a further passage through the passage opening 56, particularly advantageously be coupled out of the used beam path of the imaging radiation 14 again. In accordance with a variant of this embodiment, the reflectivity of the regions of the mirrors M7 and M8 that are used only by the measurement beam path 66 can be optimized for the measurement wavelength.

Depending on the design of the projection lens 50, the measurement beam path 66 can be reflected back through the passage opening 56 of the mirror M8 not via the substrate 36, but via a mirror element that is attached next to the substrate 36 to the substrate holder 38.

As is illustrated in FIG. 2, the measurement radiation 64 is incident, after the further passage through the passage opening 56, on a detection system 72. During the further passage, the measurement beam path 64 is tilted by the angle α₂ with respect to the used beam path of the imaging radiation 14 at the site of the passage opening 56. This situation is illustrated in FIG. 2 in the circular region in enlarged illustration. The orientation of the measurement beam path 66 during the further passage through the passage opening 56, defined by the average propagation direction of the measurement radiation 64, is illustrated here by way of the dashed arrow 66b. The orientation of the used beam path, defined by the average propagation direction of the imaging radiation 14, is illustrated by way of the arrow 54a. The angle α₁ between the straight lines defined by the arrows 54a and 66b is at least 1°, in particular at least 2° or at least 5°.

The detection system 72 can be used to measure different properties of the projection lens 50 and record the changes thereof over time. One example of such a property is a lateral imaging stability of the projection lens 50 or stability of the image position, i.e. position of an image of a mask structure 28 in the image plane 24, also referred to as “line of sight”. In the present exemplary embodiment, the influence of the last two mirrors M7 and M8 on the lateral imaging stability of the projection lens 50 can be captured by recording the position of the measurement radiation 64 on a detection surface 74 of the detection system 72. Lateral imaging aberrations over time can be produced e.g. by thermal effects that are induced by the imaging radiation 14 on the mirrors. Assuming that the main contribution of lateral imaging aberrations are due to the mirrors M7 and M8, this result can be considered an approximation of the lateral imaging stability of the overall projection lens 50.

The detection system 72 can furthermore be configured for the interferometric evaluation of the measurement radiation 64 that is incident on the detection surface 74. This can be accomplished for example by superimposing the measurement radiation 64, which is incident on the detection surface 44, with a reference radiation that is diverted from the measurement radiation 64 on the side of the measurement radiation source 62, i.e. before the measurement radiation 64 is incident on the mirror M7, and guided directly to the detection system 72. This can be accomplished e.g. as shown in US 2007/0080281A1 or using an optical fiber. The measurement apparatus 60 can be configured in particular as a Mach-Zehnder setup.

Interferometric evaluation allows, for example, a determination of positional displacements of the mirrors M7 and M8 in the axial direction over time as a property of the projection lens 50 to be measured. It is furthermore possible by way of interferometric evaluation to capture a surface deformation, occurring for example due to temperature differences over time, of the mirror M7 or of the mirror M8 in the irradiation sections 68 and 70 as a property of the projection lens 50 that is to be measured. Due to the arrangement of suitable differently configured measurement beam paths, it is optionally possible for different irradiation sections on the mirrors M7 and M8 to be measured.

The detection system 72 can furthermore record, in spatially resolved fashion, intensity changes of the measurement radiation 64 that is incident on the detection surface 74, and consequently transmission changes of the section of the projection lens 50 that is formed by the mirrors M7 and M8 with reference to the cross section of the measurement beam path 66 over time. Said transmission changes can be caused by contamination on the mirrors M7 and/or M8. Consequently, the property of the projection lens 50 that is to be measured can relate to a contamination of the mirrors thereof. The transmission changes can furthermore be caused by streaks of residual gas (e.g. H₂) in the projection lens 50. Consequently, the property of the projection lens that is to be measured can also relate to a streak determination within the projection lens 50.

Through the recording of intensity changes of the measurement radiation 64, it is furthermore possible for reflectivity changes in the irradiation sections 68 and 70 of the mirrors M7 and M8, for example of thermal origin, to be determined. Such reflectivity changes can be due to changes in the condition of surface layers of the mirrors M7 and M8. Consequently, the property of the projection lens 50 to be measured can comprise a constitution of at least one section of one or more surface layers of the mirrors M7 and M8.

In addition to said reflectivity changes, the condition change that is to be measured can also relate e.g. to a change in the polarization effect of the surface layers of the mirrors M7 and M8. In this respect, the measurement apparatus 60 can be configured in the form of an ellipsometric measurement apparatus, i.e. the measurement radiation 64 generated by the measurement radiation source 62 is at least partially polarized and the detection system 72 is configured for the measurement of the polarization state. In particular, different polarization states are sequentially used and analyzed systematically in this measurement mode, e.g. radially or tangentially polarized light, circularly polarized light or more general polarization states.

The detection system 72 can furthermore be configured for recording an angle distribution of the measurement radiation 64 that is incident on the detection surface 74. It is possible to obtain herefrom further information relating to deformations and/or surface layer changes of the mirrors M7 and M8.

The measurement radiation 64 can furthermore also be used to determine the lateral position of an alignment mark, for example in the form of a grating structure, that is arranged on the surface 34 of the substrate 36, and consequently to adjust the substrate 36 before the exposure thereof. To this end, the alignment mark can be imaged directly onto the detection system 72. Alternatively, a reference mark can additionally be arranged in the measurement beam path 66, for example on a reference mirror. One possibility for lateral position determination comprises the moire measurement method, which is known in principle to a person skilled in the art.

According to an exemplary embodiment, a grating structure that is arranged on the surface 34 of the substrate 36 is illuminated with the measurement radiation 64 in the form of white light. Depending on the local temperature, the grating size varies when using material with a non-zero coefficient of thermal expansion for the substrate 36. At the same time, the diffraction angles change via the wavelengths in the white light, and ultimately the spectral distribution of the radiation that passes to the detection system 72 and provides, after the measurement, information relating to the substrate temperature varies.

In accordance with a further embodiment of the measurement apparatus 60 (not illustrated in the drawings), the measurement radiation 64 is radiated via the passage opening 56 onto the mirror M7 such that the measurement radiation 64 is incident on a detection system 72, which is arranged in the object plane 18, via reflection at the mirrors M8, M7, reflection at the surface 34 of the substrate 36, a further passage through the passage opening 56 and a reflection at the mirrors M6, M5, M4, M3, M2 and M1.

This embodiment has the advantage of automatically well corrected imaging, for example of an alignment mark that is arranged on the surface 34 of the substrate 36, and of the inclusion of all mirrors of the projection lens 50, in particular regions of the mirrors that are of particular interest, in the measurement beam path. However, this measurement beam path might render it necessary to interrupt the exposure operation to perform the measurement, which would entail losses in throughput. However, the implementation allows the measurement of the projection lens 50 in a single passage through the beam path of the projection lens 50, which is associated with a gain in the transmission of the measurement radiation 64 as compared to a double passage. It is thus possible to operate at low intensities for the measurement radiation 64, as a result of which thermal contributions to the mirrors M1 to M8 by the measurement radiation can be reduced.

The above description of exemplary embodiments is to be understood to be by way of example. The disclosure effected thereby firstly enables the person skilled in the art to understand the present invention and the advantages associated therewith, and secondly encompasses alterations and modifications of the described structures and methods that are also obvious in the understanding of the person skilled in the art. Therefore, all such alterations and modifications, insofar as they fall within the scope of the invention in accordance with the definition in the accompanying claims, and equivalents are intended to be covered by the protection of the claims.

### LIST OF REFERENCE SIGNS

10 Projection exposure apparatus
12 Radiation source
14 Imaging radiation
16 Object field
18 Object plane
20 Illumination optical unit
22 Image field
24 Image plane
26 Mask
28 Mask structures
30 Reticle holder
32 Reticle displacement drive
34 Surface
36 Substrate
38 Substrate holder
40 Substrate displacement drive
42 Entering ray beam
44 Emerging ray beam
50 Projection lens
52 Chief ray
54 Coma rays
54a Orientation of the used beam path
56 Passage opening
58 Mirror center
60 Measurement system
62 Measurement radiation source
64 Measurement radiation
66 Measurement beam path
66a Orientation of the measurement beam path
66b Orientation of the measurement beam path
68 Irradiation section
70 Irradiation section
72 Detection system
74 Detection area
M1 to M8 Mirror

What is claimed is:

1. A device comprising a projection lens for a microlithographic projection exposure apparatus and a measurement apparatus configured to measure a property of the projection lens, wherein the projection lens comprises a plurality of optical elements for imaging mask structures onto a surface of a substrate by projecting the mask structures with imaging radiation that travels along a used beam path, wherein at least one of the optical elements comprises an opening, and wherein a measurement beam path extends through the opening.

2. The device according to claim 1,
wherein the opening is arranged at a decentralized location in the optical element.

3. The device according to claim 1,
wherein the measurement apparatus is configured to orient the measurement beam path at the site of the opening to be tilted by at least 1° with respect to the used beam path.

4. The device according to claim 1,
wherein the measurement apparatus is configured to orient the measurement beam path to be incident on at least one further one of the optical elements.

5. The device according to claim 4,
wherein the measurement apparatus is configured to measure a surface shape of at least a section of the further optical element as the property being measured.

6. The device according to claim 4,
wherein the measurement apparatus is configured to measure a constitution of at least a section of at least one surface layer of the further optical element as the property being measured.

7. The device according to claim 4,
wherein the measurement apparatus is configured to measure a transmission behavior or a reflection behavior of at least a section of the further optical element as the property being measured.

8. The device according to claim 1,
wherein the measurement apparatus is configured to measure a lateral imaging stability of the projection lens as the property being measured.

9. The device according to claim 1,
wherein the optical element having the opening is configured as a mirror.

10. The device according to claim 1,
which is configured for operation in the extreme ultraviolet (EUV) wavelength range.

11. The device according to claim 1,
wherein the optical element having the opening is a last of the optical elements of the used beam path preceding an image plane.

12. The device according to claim 1,
wherein at least one of the optical elements is configured as a mirror, which is operated at grazing incidence in the used beam path.

13. The device according to claim 1,
wherein the measurement apparatus is configured for ellipsometric measurement of measurement radiation which is guided in the measurement beam path.

14. A microlithographic projection exposure apparatus comprising the device according to claim 1.

15. The microlithographic projection exposure apparatus according to claim 14,
wherein the measurement apparatus is configured to orient the measurement beam path and to measure the property during an imaging operation of the projection exposure apparatus.

16. A method for measuring a projection lens for a microlithographic projection exposure apparatus, having a plurality of optical elements for imaging mask structures onto a surface of a substrate by projecting the mask structures with imaging radiation that travels along a used beam path, wherein at least one of the optical elements is formed with an opening, said method comprising radiating measurement radiation that differs from the imaging radiation through the opening of the at least one optical element.
